(19) United States
(12) Patent Application Publication
(10) Pub. No.: US 2020/0346939 A1
(43) Pub. Date: Nov. 5, 2020

(54) DEVICES CONTAINING CONDUCTIVE MAGNESIUM OXIDES

(71) Applicant: SHELL OIL COMPANY, HOUSTON, TX (US)

(72) Inventor: Michael KANDIANIS, Houston, TX (US)

(21) Appl. No.: 16/863,234

(22) Filed: Apr. 30, 2020

Related U.S. Application Data
(60) Provisional application No. 62/840,854, filed on Apr. 30, 2019.

(51) Int. Cl. C01F 5/02; H01L 29/24; H01L 29/51; H01M 4/62; H01M 10/42

(52) U.S. Cl. CPC C01F 5/02; H01L 29/24; H01L 29/517; C01P 2002/82; H01M 10/4235; C01P 2006/40; C01P 2006/80; H01M 4/621

(57) ABSTRACT

Devices containing novel conductive monocrystalline magnesium oxides are provided. The devices may be an energy storage device, a wide band gap semiconductor, or a gate dielectric. The conductive monocrystalline magnesium oxides have a purity of at least 98% and have an imaginary contribution to the dielectric permittivity (ε″) of at most 0.03 at a frequency of 0.031 Hz or have a conductivity of at least 10^{-8.4} S*m⁻¹ at a frequency of 0.031 Hz. Certain conductive monocrystalline magnesium oxides have a positive charge density.

### CROSS-REFERENCE TO RELATED APPLICATION

This application claims the benefit of U.S. Provisional Patent Application No. 62/840,854, filed Apr. 30, 2019, which is incorporated by reference herein in its entirety.

### FIELD OF THE INVENTION

This invention relates to certain devices containing conductive magnesium oxide crystals.

### BACKGROUND OF THE INVENTION

Interactions among electrons within confined geometries give rise to some of the most fascinating properties of materials. Breakthrough discoveries that include high-temperature superconductivity, giant magnetoresistance, and topological phases are notable examples. Combinations of rare and earth abundant elements alike now provide a doorway to rich phenomena where novel properties originate from the same recipe: the redistribution of electronic order in condensed matter.

Harboring distinct electronic behavior in materials ultimately depends on the symmetry state of the containing phase. As an example, characteristic wavefunction topology or structural asymmetry both can sponsor semimetallic behavior in a wide-range of lattice classes. But for materials that possess a center of inversion and trivial band structure, the options for electronic reshuffling are more limited. The search for novel electronic properties in these phases relies heavily on heterostructure and interface engineering that aims to amplify charge transport, incite electronic reconstruction, or sponsor correlated electron movement. Materials with modified electronic structure are necessary to fulfill a wide-variety of needs.

Monocrystalline Magnesium Oxide (MgO, Periclase), like other rocksalt-structured oxides of the Fm3m space group, exhibits a bulk centrosymmetric character with mirror symmetry along the 110 plane. The cubic close packed arrangement of MgO arises from repeating layers of interpenetrating octahedra wherein Mg atoms or O atoms rest in six-fold coordination to each other (FIG. 1). Charge density arising from a divergence in electric fields at surface termini are inherent characteristics of natural MgO. This is depicted in FIG. 1 where the top-most negative charge forms a dipole oriented into the crystalline bulk that remains uncompensated at the crystal surface.

Investigations of the MgO electronic structure demonstrate that net charge density is also present within the crystalline bulk of this material. Such findings are consistent with the homostructural nature of planes along [111] in rocksalt with those perpendicular to [001] in crystals from the 3̅m point group, a symmetry known to support current density and linear momentum. Momentum flux and the transmission of current in natural MgO are limited by its extremely low conductivity as natural MgO is an electrical insulator with a band gap of 7-8 eV. The high energy required to transport electrons or holes in this material necessitates that crystals of natural MgO be doped with metals or fashioned into ceramics with other oxides to enable its use in electronic applications. Natural MgO also suffers from dielectric breakdown in strong electric fields as leakage currents and breakthrough conductivity prevent its operating reliably once the imposition of charge exceeds its capacity for charge storage.

### SUMMARY OF THE INVENTION

It has been found that a new composition of matter can be produced by modifying the number of accessible bonding states of natural MgO such that MgO is transformed into a new or novel MgO phase that exhibits enhanced conductivity and/or low dielectric loss by certain methods. The novel MgO is stable and can be characterized for example by its distinct imaginary contribution to the dielectric permittivity. This novel conductive material may be useful as a component in energy storage devices, as wide band gap semiconductors and as gate dielectrics due to its enhanced conductivity and low dielectric loss.

In an embodiment, an energy storage device, a wide band gap semiconductor, or a gate dielectric comprises a conductive monocrystalline magnesium oxide having a purity of at least 98%, and having an imaginary contribution to the dielectric permittivity (ε″) of at most 0.03 at a frequency of 0.031 Hz.

In another embodiment, an energy storage device, a wide band gap semiconductor, or a gate dielectric comprises a conductive monocrystalline magnesium oxide having a purity of at least 98% and a conductivity of at least 10^{-8.4} S*m⁻¹ at a frequency of 0.031 Hz.

In some embodiments, the conductive monocrystalline magnesium oxide described herein has a positive charge density.

In some embodiments, the conductive monocrystalline magnesium oxide described herein has a purity of at least 99%.

In some embodiments, the conductive monocrystalline magnesium oxide described herein has a conductivity of at least 10^{-8.4} S*m⁻¹ at a frequency of 0.031 Hz.

In some embodiments, the conductive monocrystalline magnesium oxide described herein has an increased Raman scattering intensity in the 1019 cm⁻¹ range compared to natural monocrystalline magnesium oxide.

In some embodiments, the conductive monocrystalline magnesium oxide described herein has a charge density of at least 1000 C*m⁻³.

In another embodiment, an energy storage device comprises at least one of electrodes, electrolytes, binders, or combinations thereof wherein said electrodes, electrolytes, binders, or combinations thereof comprises a conductive monocrystalline magnesium oxide having a purity of at least 98% and an imaginary contribution to the dielectric permittivity (ε″) of at most 0.03 at a frequency of 0.031 Hz.

In another embodiment, an energy storage device comprises at least one of electrodes, electrolytes, binders, or combinations thereof wherein said electrodes, electrolytes, binders, or combinations thereof comprises a conductive monocrystalline magnesium oxide having a purity of at least 98% and having a conductivity of at least 10^{-8.4} S*m⁻¹ at a frequency of 0.031 Hz.

In some embodiments, at least one electrode comprises the conductive monocrystalline magnesium oxide.

In some embodiments, at least one electrolyte comprises the conductive monocrystalline magnesium oxide.

In some embodiments, at least one binder comprises the conductive monocrystalline magnesium oxide.

In another embodiment, a wide band gap semiconductor comprises a conductive monocrystalline magnesium oxide having a purity of at least 98%, an imaginary contribution to the dielectric permittivity (ε″) of at most 0.03 at a frequency of 0.031 Hz, and having a conductivity of at least 10^{-8.4} S*m⁻¹ at a frequency of 0.031 Hz.

In another embodiment, a gate dielectric comprises a conductive monocrystalline magnesium oxide having a purity of at least 98%, an imaginary contribution to the dielectric permittivity (ε″) of at most 0.03 at a frequency of 0.031 Hz, and having a conductivity of at least 10^{-8.4} S*m⁻¹ at a frequency of 0.031 Hz.

The features and advantages of the invention will be apparent to those skilled in the art. While numerous changes may be made by those skilled in the art, such changes are within the spirit of the invention.

### BRIEF DESCRIPTION OF THE DRAWINGS

The drawings illustrate certain aspects of some of the embodiments of the invention, and should not be used to limit or define the invention

FIG. 1 depicts charge layering within the [111] crystal direction of MgO, an ionic oxide with rocksalt structure.

FIG. 2 is a graph showing dependence of charge density (ρ) on the modulation period (τ) for natural MgO (MgO) and conductive monocrystalline magnesium oxide (MgO*).

FIG. 3 is a graph showing the dependence of the imaginary contribution to the dielectric permittivity (ε″) and the electrical conductivity (σ) on frequency (inset) for natural magnesium oxide (MgO) and conductive monocrystalline magnesium oxide (MgO*).

FIG. 4 is a second order Raman spectrum of MgO* and MgO; Raman scattering intensity is plotted versus Raman shift as measured in wavenumber (cm⁻¹) for both materials.

FIG. 5 shows surface microtopographic maps of natural MgO and the conductive magnesium oxide acquired using atomic force microscopy (AFM) as described in the Illustrative example below.

FIG. 6 is a graph showing the evolution of force imposed on a uniaxial load cell platen by MgO and MgO* under conditions of zero axial stress and continuous exposure of the oxide single crystal surfaces to an undersaturated aqueous solution flowing at 5 ml/min.

### DETAILED DESCRIPTION OF THE INVENTION

This disclosure relates to a new material composed of a conductive monocrystalline or single crystalline magnesium oxide having a purity of at least 98% and having enhanced conductivity and/or low dielectric loss compared with natural magnesium oxide. The monocrystalline magnesium oxide preferably has a purity of at least 99%, more preferably at least 99.3%, at least 99.5%, and at least 99.7%. The purity is such that it is undoped, meaning no other added metals, metalloids, alkali-metals or semi-metals beyond natural impurities.

The disruption of spatial inversion symmetry at surface termini often produces electric fields that initiate band bending and induce lattice polarization. As these fields diverge at interfaces, charge density as well as transient depolarization currents can arise in dielectric materials. Anomalies in the bulk electron density of MgO indicate that the polarization of this centrosymmetric oxide, rather than being a product of broken symmetry or crystallographic strain, may result from a flexible oxygen sublattice with the capacity for breathing. Theoretical investigations ascribe such breathing to distortions in oxygen 2s or 2p orbitals; whereas other modelling work indicates MgO to be rigidly ionic and attributes the formation of charge density to variations in coordination at its surfaces. Differentiating whether the presence of charge is a product of surface formation or arises from the symmetry of the bulk lattice is essential for understanding the electronic behavior of ionic oxides with rocksalt structure.

To isolate the effect of surface specific fields on oxide electrical properties, we employed a modulated annealing technique that infuses oxygen into the MgO lattice and alters the near surface bulk to create distinct MgO compositions. After annealing or equilibrating single crystals in nitrogen gas (N₂), we explored the electronic character of the oxides using a suite of approaches specially designed to characterize bulk and surface electrical properties in situ. The measurement of charge (q) dynamics, captured using an ammeter emplaced within the nosecone of an atomic force microscope (AFM), and the independent determination of the interaction energy,

$$\frac{dF}{dx} ,$$

of the AFM probe with the MgO surface allow for the direct

$$ρ = - \frac{dF}{dx} \frac{ɛ}{q} \qquad ( 1 )$$

determination of charge density, ρ, when the AFM probe comes into coulombic contact with the near surface zone (e.g. a height of 5 to 10 nm above the surface) within a medium that exhibits a dielectric permittivity (E).

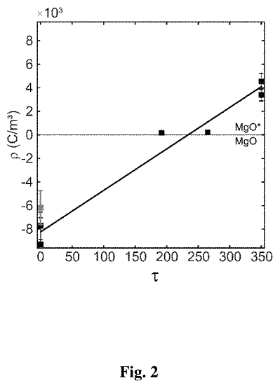

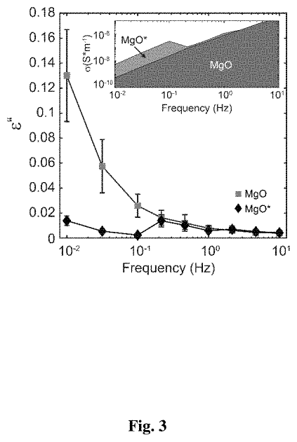

A clear distinction in the electronic character of the oxides is apparent (FIG. 2); MgO equilibrated in the absence of water vapor (≤−40 C dewpoint) in either an inert atmosphere or mixtures of ultra-high purity nitrogen (N₂) and oxygen (O₂) gas carry a net negative charge, whereas crystals undergoing modulation exhibit positive ρ values that increase linearly with the period (τ) of the modulation function. There is also a concomitant shift in the bulk electrical properties of materials (FIG. 3) that underwent the maximal modulation annealing period (MgO*) relative to the native oxide (MgO). Single crystal AC conductivity values skew 1 to 1.5 orders of magnitude higher in MgO* at frequencies between 0.01 and 0.1 Hz, while the imaginary contribution to the dielectric permittivity (ε″) is nine to eleven-fold lower for this material over the same frequency range.

One consistent feature among all MgO materials is the presence of small (pA), but persistent currents. This finding, first observed using current sensing AFM (CS-AFM), is also consistent with direct current (DC) measurements made with a source measurement unit (SMU) attached directly to surfaces of MgO single crystals.

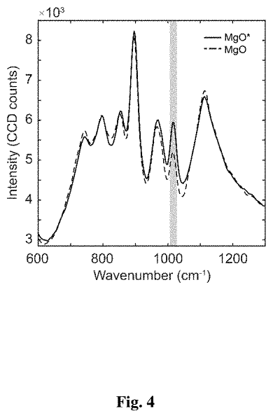

The reversal in current direction for MgO with τ>0 demonstrates the control that interfacial structure can have on the electric properties of oxides with centrosymmetric rocksalt symmetry. Materials that undergo modulated annealing exhibit surface electric fields oriented away from the bulk lattice, suggesting that a reduced potential for energy dissipation through Joule heating and the conductivity enhancement of MgO* result from the formation of space charge layers in the near-surface bulk that alter the mechanisms of charge carrier transport. Second order Raman spectra (FIG. 4) of MgO and MgO*, obtained with a confocal Raman microscope focused on the top-most ˜1000 unit cells of the oxides, confirms that the infusion of oxygen into the interface via modulation has an influence that extends into the MgO bulk. At a Raman shift of 1019 cm⁻¹, an energy where the doubly (E_{g}) and triply (T_{2g}) degenerate orbitals experience local maxima and overlap with nondegenerate (A_{1g}) orbitals, there is a 15% difference in the density of vibrational states (DOS) for conductive monocrystalline magnesium oxide.

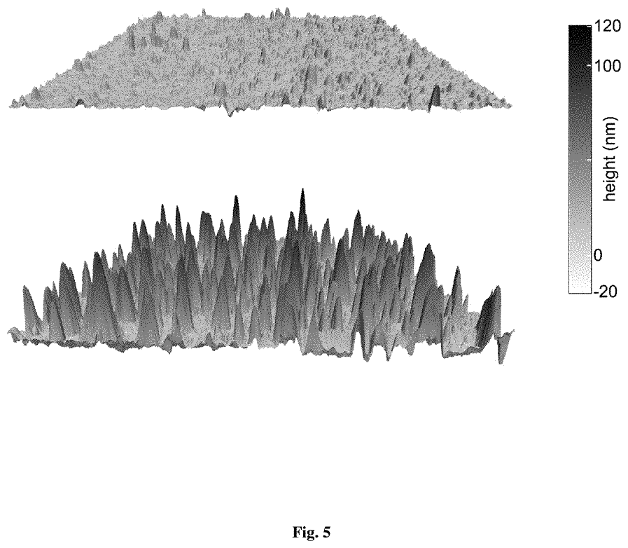

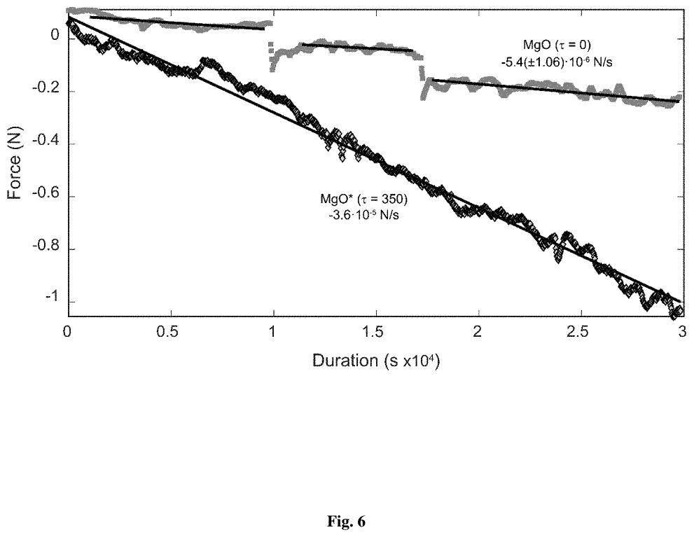

After dissolving the crystal surfaces of MgO and MgO* with an undersaturated aqueous solution, the conductive monocrystalline magnesium oxide exhibits persistent current density that gives rise to the enhanced assembly of magnesium hydroxide (Mg(OH)₂) on the surface of this material relative to natural MgO (FIG. 5). Constant momentum flux from both MgO and MgO* further demonstrates that disruption in surface structure is unable to perturb the transmission of energy from magnesium oxide (FIG. 6); still, the elevated force imposed by MgO* on its surroundings relative to natural MgO over the duration of the experiments is an effect directly related to the increased conductivity of the MgO* material.

To create a magnesium oxide (MgO) single crystal with persistent currents, low imaginary capacitance (low dielectric loss), and high conductivity, a modulated annealing can be used that ensures dry ultra-high purity (UHP) oxygen gas can permeate the MgO lattice beyond the surface layer. To make the conductive monocrystalline magnesium oxide of the invention, an annealing method can be used. Any monocrystalline magnesium oxide of sufficient purity can be used as the starting material whether natural or synthetized. Such monocrystalline magnesium oxides are commercially available. The monocrystalline magnesium oxide is exposed to nitrogen gas (this is high purity nitrogen gas and not air), then oxygen gas (this is high purity oxygen gas and not air), then again similar nitrogen gas, then similar oxygen gas and similar nitrogen gas for an effective time to produce the conductive monocrystalline magnesium oxide having an imaginary contribution to the dielectric permittivity (ε″) of at most 0.03 at a frequency of 0.031 Hz and/or a conductivity of at least 10^{-8.4} S*m⁻¹ at a frequency of 0.031 Hz.

An example of preparation may involve taking a pre-cleaved single MgO crystal under the constant flow of dry ultra-high purity (UHP) N₂ gas; and transfer the MgO crystal to an environmentally controlled chamber under conditions where the partial pressure of water vapor is kept to a minimum (e.g., at −40° C. dew point, and 3.791/min flow of UHP N₂) heated to a temperature in a range of above ambient conditions, preferably at least 30° C., more preferably at least 35° C., but less than 80° C., preferably less than 60° C., more preferably less than 55° C., and preferably at about atmospheric pressure (e.g., 0.1 MPa pressure). Upon thermal equilibration of the crystal (e.g., over a period of 10 min) where the temperature variability of the chamber in which the crystal is located is less than 0.1° C. per minute. UHP gas flow (N₂ or O₂) is set to establish a residence time of a gas at a range of preferably 3 to 5 seconds at a constant flow rate and temperature.

In the modulated annealing process the composition of gas is varied between UHP N₂ and UHP O₂ over time in a manner consistent with the following framework; step 1—N₂(1) followed by step 2-θ₂(1), step 3-N₂(2), step 4-θ₂(2) and step 5-N₂(3). Temperature and pressure remain constant until step 4 where temperature is raised to at least 40° C. for a time effective to equilibrate the system at this new temperature (e.g., 30 min prior to the end of the step). The temperature in the final step, 5, remains at least 40° C., but less than 80° C., preferably less than 60° C., more preferably less than 55° C. and the flow rates of UHP N₂ are increased to residence time of N₂ in the range of preferably 1 to 2.5 sec for a period of at least 30 minutes up to 3 hours, preferably approximately 1 hour. After step 5, to maintain the material pure for an indefinite time, the annealed product may be kept under UHP N₂ flow at a residence time in the range of at least 12 seconds to at most 20 seconds. The annealed product may also be maintained at room temperature but preferably at a partial pressure of water less than 10⁻³ atm.

In an embodiment a method to increase the conductivity of a magnesium oxide crystal is provided, comprises:
(a) providing a single crystal magnesium oxide,
(b) contacting the single crystal magnesium oxide with nitrogen gas at a temperature in the range of at least ambient temperature to at most 80° C. (and preferably a pressure in the range of 0.1 MPa to 0.15 MPa) thereby providing a first nitrogen contacted magnesium oxide;
(c) contacting the first nitrogen contacted magnesium oxide with oxygen gas at a temperature in the range of the range of at least ambient temperature to at most 80° C. (and preferably a pressure in the range of 0.1 MPa to 0.15 MPa) thereby providing a first oxygen contacted magnesium oxide;
(d) contacting the first oxygen contacted magnesium oxide with nitrogen gas at a temperature in the range of the range of at least ambient temperature to at most 80° C. (and preferably a pressure in the range of 0.1 MPa to 0.15 MPa) thereby providing a second nitrogen contacted magnesium oxide;
(e) contacting the second nitrogen contacted magnesium oxide with oxygen gas at a temperature in the range of at least 40° C. to at most 80° C. (and preferably a pressure in the range of 0.1 MPa to 0.15 MPa) thereby providing a second oxygen contacted magnesium oxide; and
(f) contacting the second oxygen contacted magnesium oxide with nitrogen gas at a temperature in the range of at least 40° C. to at most 80° C. (and preferably a pressure in the range of 0.1 MPa to 0.15 MPa) thereby providing the increased conductivity magnesium oxide crystal.

This modulated annealing process allowed for the alteration of the bulk crystalline structure such that the conductivity was increased. Even after dissolving the crystal surface, increased current density persisted as demonstrated by the significantly higher rates growth rate of Mg(OH)₂ on the MgO structure on the surface upon contact with H₂O.

It was found that the monocrystalline magnesium oxide produced by the above annealing method is conductive. The conductive monocrystalline magnesium oxide of the invention has an imaginary contribution to the dielectric permittivity (ε″) of at most 0.03, preferably at most 0.025, more preferably at most 0.015 measured at a frequency of 0.031 Hz measured by AC impedance spectroscopy as described in the method below. The conductive monocrystalline magnesium oxide has a neutral or positive charge density compared to the negative charge density exhibited by natural monocrystalline magnesium oxide. Preferably the conductive monocrystalline magnesium oxide of the invention has a positive charge density. More preferably the charge density of the conductive monocrystalline magnesium oxide is at least 1000 C*m⁻³. The conductive monocrystalline magnesium oxide of the invention has an increased Raman scattering intensity in the 1019 cm⁻¹ range compared to natural monocrystalline magnesium oxide measured by Raman Spectroscopy. The increase is preferably at least by 5%, more preferably 10%, even more preferably 15%. The location of the peak Raman scattering intensity in the 1019 cm⁻¹ range may vary depending on the instrument and excitation wavelength by about ±5 cm⁻¹. The conductive monocrystalline magnesium oxide may have a conductivity of at least 10^{-8.4} S*m⁻¹, preferably at least 10⁻⁸ S*m⁻¹ at a frequency of 0.031 Hz as measured by AC impedance spectroscopy as described by the method below.

The conductive monocrystalline magnesium oxide may be incorporated into various devices that require conductivity. This novel conductive material may be useful as a component in energy storage devices, as a wide band gap semiconductor, and as a gate dielectric due to its enhanced conductivity and low dielectric loss.

For example, an energy storage device can contain at least one of electrodes, electrolytes, binders, or combinations thereof, such electrodes, electrolytes, binders or combinations thereof containing the conductive monocrystalline magnesium oxide described above. The electrodes may be either cathodes or anodes. Electrolytes are media for transferring ions and/or electrons between contacts, electrodes or plates. Electrolytes can also be referred to as the dielectric in certain devices. Binder refers to a material that separates an anode or a cathode from the electrolyte in the energy storage devices. The use of the conductive monocrystalline magnesium oxide within energy storage devices would avert the breakdown of the battery architecture that invariably results from cycling charge. As shown in FIG. 6, the invariant current density of conductive monocrystalline magnesium oxide (denoted as MgO*) before and after the imposition of electrical force demonstrates that this material provides enhanced stability under conditions that are similar to the operational environments for batteries, capacitors and hybrid storage devices. The enhanced conductivity of the conductive monocrystalline MgO can provide improved charging efficiency and can may be incorporated into binder materials to allow charge transfer reactions to proceed at accelerated rates so that ions or electrons are quickly generated or consumed in energy storage devices. Examples of energy storage devices can be found in U.S. Pat. No. 9,263,894, entire disclosures are hereby incorporated by reference, and more specifically such as in batteries can be found in U.S. Pat. No. 8,940,446, US patent publication no. 20190036171, entire disclosures are hereby incorporated by reference.

For example, a wide band gap semiconductor can contain the conductive monocrystalline magnesium oxide described above. Wide band gap semiconductors are essential materials for high voltage power transmission and the production of semiconductor lasers. Employing conductive monocrystalline magnesium oxide as a wide band gap semiconductor provides a new material with high breakdown voltage that exhibits lower Joule heating during operation, which is particularly important for materials exposed to substantial electric fields. These characteristics enable improved management of power switching and reduced energy dissipation during transmission as well as operational efficiency at higher temperatures. Examples of wide band-gap semiconductors can be found in U.S. Pat. Nos. 5,252,499, 8,039,792, 8,017,981, entire disclosures are hereby incorporated by reference. These devices can be used as power electronics for example in automotives, data centers, aerospace, and distributed energy resources.

For example, a gate dielectric can contain the conductive monocrystalline magnesium oxide described above. A gate dielectric is an essential component of field effect transistors that ensures the efficient transfer of energy from its source to its drain. By using the conductive monocrystalline magnesium oxide of the invention as a gate dielectric instead of, for example, SiO₂, dielectric losses in transistors are reduced thereby extending the lifetime of these devices. Examples of gate dielectric can be found in U.S. Pat. Nos. 7,115,461, 8,652,957, 9,006,094, entire disclosures are hereby incorporated by reference. While the invention is susceptible to various modifications and alternative forms, specific embodiments thereof are shown by way of examples herein described in detail.

It should be understood, that the detailed description thereto are not intended to limit the invention to the particular form disclosed, but on the contrary, the intention is to cover all modifications, equivalents and alternatives falling within the spirit and scope of the present invention as defined by the appended claims. The present invention will be illustrated by the following illustrative embodiment, which is provided for illustration only and is not to be construed as limiting the claimed invention in any way.

### Illustrative Examples

Examples of preparing the novel conductive monocrystalline magnesium oxides and its characterization follows.

Methods

Preparing MgO Single Crystals with Novel Electrical Properties

To prepare magnesium oxide single crystals with distinct electrical properties, (110) oriented, ultrapure (>99.95%) magnesium oxide crystals with sizes of 5×5, 10×10 and 20×20 mm and a thickness of 0.5 mm were purchased from MTI Corporation (www.mtixtl.com). At the manufacturer, both crystal sides were polished by chemical-mechanical planarization providing minimal sub-surface damage. The surface roughness was determined to be <1 nm and all crystals were stored in a vacuum chamber prior to use. Sample preparation in the laboratory involved the following steps; (1) removal of pre-cleaved single crystal from a vacuum chamber/desiccator while keeping the material under the constant flow of dry ultra-high purity (UHP) N₂ gas; placement of the crystal on a glass microscope slide; and (2) immediate transferal of the oxide crystal to an environmentally controlled chamber that is held at −40° C. dew point, and 3.79 l/min flow of UHP N₂ gas heated to a temperature of 38.5° C. at 0.1 MPa pressure. Upon closing the chamber, thermal equilibration over a period of 10 min is established with less than 0.1° C. temperature variability per min and the UHP N₂ gas flow is set to 15.27 l/min constant flow rate and temperature. The modulated annealing process to produce MgO* begins wherein the composition of gas is varied between UHP N₂ gas and UHP O₂ gas over time in a manner consistent with the following framework; Gas 1—N₂(1) followed by Gas 2—O₂(1), Gas 3—N₂(2), Gas 4—O₂(2) and Gas 5—N₂(3). Temperature and pressure remain constant until step 4 where temperature is set to 42.5° C. at a time equivalent to 30 min prior to the end of the step. The temperature in the final step, 5, remains at 42.5° C. and flow rates of UHP N₂ are increased to 20.49 l/min for 1 hour. After step 5, the prepared material remains in an environmental chamber at UHP N₂ flow rates of 3.79 l/min, 42.5° C., 0.1 MPa and −40° C. dew point until further analysis or reaction is undertaken. The duration of interval 1 (specified here as a cycle between the midpoint of N₂(1) and N₂(2)) is denoted as τ₁; and the duration of interval 2 (specified here as a cycle between the midpoint of N₂(2) and N₂(3)) is τ₂. Modulated annealing occurs through the modification of τ₁ and τ₂ in accord with an approach that minimizes the difference frequency between intervals and maximizes the distinction between the sum frequency and the difference frequency, while ensuring both frequencies are greater than zero. If we consider that the frequencies describing intervals 1 and 2 are f₁=1/τ₁ and f₂=1/τ₂, respectively, we can define the time (t) dependent modulation function (ψ(t)) that accounts for the sum and difference frequencies as ψ(t)=2 sin {πt(f₁+f₂)} cos {πt(f₁−f₂)}. As an example, for τ₁=795 min and τ₂₌₁₉₅ min, f₁ and f₂ would equal 1/795 min and 1/195 min, respectively; the average difference frequency would equate to 32.2 μHz and the average sum frequency would equal 53.2 μHz. In this scenario, such frequency matching would yield a period (τ) of ψ(t) equivalent to 197±10 min thereby ensuring that modulated-annealing will allow for the amplification of oxygen exposure to the oxide by way of producing beats that propel dry UHP O₂ into the crystal while maintaining a surface layer free of excess oxygen. The process to produce MgO crystals follows the same preparatory approach, gas flow rate variations, and temperature scheme as that detailed in the modulated annealing procedure but involves the exclusive use of UHP N₂ gas for the entire equilibration period, and therefore exhibits no modulation

The conductive monocrystalline magnesium oxides produced were measured by the methods mentioned below and the results provided in FIGS. 2 to 6.

Atomic Force Microscopy

Experiments were carried out in an Agilent/Keysight Technologies 5500 atomic force microscope (AFM) mounted to an environmental chamber that allows for the full control of temperature, flow rates and composition of fluid and gas atmospheres. AFM imaging was carried out using CDT-NCH and RM Platinum tips (Rocky Mountain Nanotechnology) with force constants between 65 to 115 N/m. MgO single crystals were mounted to the AFM sample plate using either vacuum grease for dry and controlled humidity experiments or a fluid cell, acting as a clamp, during the experiment. Prior to the AFM experiments, MgO crystals were exposed to varying UHP N₂ and O₂ mixtures as described in section “Preparing MgO single crystals with distinct electrical properties”. For the case of fluid cell experiments, an undersaturated solution (0.0098 S/m) prepared by dissolving MgO in ultrapure MilliQ water was flowed at a rate of 5 ml/min and at a temperature of 42.5° C. across the annealed MgO crystals for durations ranging from a few minutes to many hours. During the experiment, a N₂ gas (0.1 MPa at 3.79 l/min) was continuously flowed through the environmental chamber. After the experiment, reacted MgO crystals were immediately submerged into liquid-N₂ and vacuum dried (10⁻⁷ MPa) for up to 12 hours to sublimate all liquid from the surface and avoid post-experimental alteration of the crystals. AFM topography scans were performed on all experimentally reacted MgO crystals. Random scans of the reacted surface were conducted with a scan area of 20×20 μm at a resolution of 512×512 pixels giving a pixel resolution of 39 nm. From these scans, rates of Mg(OH)₂ pillar assembly were calculated.

AFM Force Spectroscopy, Current-Sensing AFM, and Direct Current Measurements

To investigate forces arising at the MgO crystal surface we developed a modified force vs. distance (FvD) spectroscopy approach that avoids surface charge dissipation. Using the scripting capability of the Keysight PicoView software package, we acquired spectroscopic plots in a quasi-continuous mode while the AFM probe approaches the crystal surface. This contrasts with conventional AFM force measurements which fully engage the surface prior to the measurement. During the customized quasi-continuous AFM spectroscopy mode, the probe approaches the crystal surface until a repulsive force is detected and exceeds a predefined limit of −0.1 V translating in forces between 125 to 750 nN with an average of 250 nN. While approaching the surface 20,000 data points within a 2 μm interval are collected. Once a repulsive force is detected the probe moved away from the surface recording the tip-sample interaction event from about 3 μm above the crystal surface. To probe for current emergent from single crystal MgO materials, an ammeter was installed inside the AFM tip holder. The sensitivity limits varied between 0.1 pA to 1 nA with a resolution of 0.1 pA. For the purposes of this measurement, we used conductive monolithic Pt probes (Rocky Mountain Nanotechnology). The electrical current is acquired simultaneously with the FvD plot, in a second channel. Since raw FvD data does not provide the tip-sample distance, but the cantilever deflection and the scanner's piezo travel, a conversion is necessary to access pertinent physical quantities. Force sensed by the probe is calculated from the cantilever deflection, deflection sensitivity and spring constant, while displacement (tip-sample distance) is obtained from the difference of the cantilever deflection, in meters, and the scanner's piezo travel. Currents arising from MgO crystal surfaces were measured using a Source and Meter Unit (SMU) from Keithley, model 2450. An area of 3 mm² near opposite edges of the equilibrated crystal surface receives silver paint to create conductive contacts, leaving the central area exposed. Copper wires are attached to the contacts and then soldered to the triaxial cables to obtain these measurements. Voltage imposed on the crystal using the SMU apparatus (from −200 to +200V) provides opportunity to measure DC conductance of the crystals with current levels as small as 0.1 pA.

Mechanical Force Measurements with Nano-Load Cell

A Psylotech μTS uniaxial load cell, with a resolution of 1 mN, was custom-fit directly to the environmental chamber. The load cell architecture was thermally isolated from the environmental chamber. Prior to the initiation of experiments with MgO, an undoped, ultra-pure Silicon (Si) single crystal with prominent (100) surfaces was fixed by epoxy to an 8 mm diameter stainless steel platen at the base of the load cell. The epoxy was left to cure for 2 hours at 60° C. and a UHP N₂ gas flow of 15.27 SLPM (standard liter per minute). During the curing step, the Si crystal was lowered onto an MgO crystal with a force of 5 N to secure perfect parallelism between Si and the polished surface of MgO. The load cell was then raised off the environmental chamber and a new MgO crystal was placed onto the sample plate and bound to it using a fluid cell. To define the surface position, the load cell was lowered to a contact force of 1-2 N. The load cell was then backed off by 1 μm in preparation for equilibration, as described in section “Preparing MgO Single Crystals with Novel Electrical Properties”, and the subsequent initiation of fluid flow at 5 ml/min for up to 45 hours at 42.5° C. The dilute solution described in section “Atomic Force Microscopy” was used as the fluid in all experiments, and flow was established for 5 minutes before the Si-capped platen was lowered in a step-wise manner to its final position (500 nm above the MgO crystal surface) using the displacement control of the load cell. This position defines the baseline for force measurement and any force emerging from the crystals was measured over time under the imposition of zero axial stress at a frequency of 1 Hz. To preserve the surface structure of crystals undergoing reaction with the solution in the load cell configuration, oxides removed from the fluid cell were treated in accord with the methods described above.

### Impedance Spectroscopy

The complex impedance was measured for MgO and MgO* crystals at the frequencies 0.01 to 10 Hz using a Solatron impedance analyser (model 1260) equipped with a dielectric interface (model 1296A). The integration time was 1 cycle for 0.01-0.1 Hz, 3 cycles for 0.1-1 Hz and is for 1-10 Hz. This configuration provides a smooth plot for the complex impedance in the frequency range of 0.01 to 10 Hz within a matter of minutes. After the equilibration, the MgO (110) crystals are removed from the equilibration chamber, while UHP (ultra-high purity) N₂ gas is sprayed on the exposed surface to reduce condensation of moisture. Both top and bottom surfaces, separated by crystals with a thickness of 0.5 mm, are covered with silver paint to create the conductive plates. Copper wires are attached to the plates and then soldered to the coaxial cables. The assembled capacitor is replaced into the equilibration chamber and complex impedance measurements are carried out only after 10 min to allow the thermal equilibration. The measurements are executed within the equilibration chamber at −40° C. dew point, and 3.79 l/min flow of UHP N₂ heated to a temperature of 42.5° C. at 0.1 MPa pressure. The area of the plates for the assembled capacitor with MgO (110) is estimated to be (l₁−1 mm) (l₂−1 mm), where l₁ and l₂ are the width and length of the crystal. For standard 10 mm×10 mm format the area is −81 mm² and for a half of that it is ˜36 mm². Values of ε″ were specified using the real and imaginary components of the impedance, the dimensions of the crystals, and the permittivity of free space; the conductivity (σ) values reported here are specified using the real impedance and the dimensions of the crystals.

### Raman Spectroscopy

Single (110) MgO crystals were exposed to N₂—O₂ gas mixtures or ultra-high purity N₂ gas in a custom-built environmental Raman cell following the equilibration procedures described in section “Preparing MgO Single Crystals with Novel Electrical Properties”. Raman spectra were collected (subsample=3) from MgO* and MgO crystals (replicates=2) using a confocal WiTec alpha 300R Raman spectrometer equipped with a 600 grooves/mm grating and 488 nm laser excitation. The scattered light was collected in a 180° backscattering geometry parallel to [110] using an approach consistent with that of other investigators. Prior to the acquisition of signal from each oxide, the spectrometer was calibrated using the first order Raman band of silica at 520.7 cm⁻¹. The integration time for all spectra was 360 seconds.

### Charge Density

dΩ=dE−TdS<0 (1)

The Helmholtz potential energy (dΩ) of a system at constant temperature (T) and volume must be less than zero for any for any process where a system does work on its surroundings. This implies that the change in energy (dE) must either be negative or be smaller in magnitude than the entropy term (TdS) on the right-hand side of (1).
If we consider a system containing a solid phase and probe that rests in the region directly above the solid surface,

dE_{sys}=dEᵢₙₜ (2)

describes the case where the contribution of external energy sources to the system energy is negligible or zero. If change in system energy is also zero

dE_{sys}=0 (3)

change in energy from internal sources is equivalent to the contributions from the system components

dEᵢₙₜ=dE_{X*}+dEₚ (4)

where (dE_{X*}) and (dEₚ) represent changes in the solid energy and the probe energy, respectively. After substituting (3) into (2) and inserting this result into (4), the internal constituents of this system

dE_{X*}=−dEₚ (5)

are necessarily equal in magnitude and opposite in sign. Further deconvolution of the right-hand side of (5) shows that energy change for the probe is equivalent to various contributions to its surface energy. As such

$$\begin{matrix}d {E}_{p} = α dA + Ad α & ( 6 ) \\ where & \\ α = \frac{E}{A} & ( 7 )\end{matrix}$$

the coefficient α is the ratio of the energy per unit probe area (A) in quasi-contact with a planar solid. If we consider that probe is semi-spherical,

$$\begin{matrix}A = 2 π {L}^{2} & ( 8 ) \\ and & \\ \partial α = \frac{Fdx}{2 π {L}^{2}} & ( 9 )\end{matrix}$$

the change in energy per area is expressible as the derivative of α in (9).
For the case where the probe area is invariant, the first term on the right-hand side of (6) is zero and after substituting (8) and (9) into (6) the energy change in the probe for any process is

dEₚ=−Fdx (10)

the force (F) applied to the probe by the solid multiplied by the change in probe displacement (x).
If we perform a gedanken experiment where a probe moves from a point distant from the surface to a fixed critical point where an interaction between the probe and the solid is zero but any further movement nearer to the solid surface would lead to an alteration of the probe state, the change in force resulting by initializing a system at discrete positions within the critical region is

$$d ( \frac{{dE}_{p}}{L} ) = - d F \qquad ( 11 )$$

where L, the effective interaction radius given by the Derjaguin approximation (Derjaguin, 1934) between a semi-spherical probe and a planar solid, is a constant that replaces the differential term on the right-hand side of (10) when the probe surface separation is small. If a variant of our experiment allows for the continuous reduction of the probe-crystal separation and simultaneous tracking of the change in force at discrete positions, the force gradient describing this situation is

$$\frac{d}{dx} ( \frac{{dE}_{p}}{L} ) = - \frac{dF}{dx} \qquad ( 12 )$$

where dx is the change in probe displacement from the critical point.
Substitution of (5) into (12) yields

$$\frac{1}{L} ( \frac{{d}^{2} {E}_{X *}}{dx} ) = \frac{dF}{dx} \qquad ( 13 )$$

and normalizing both sides of (13) by the amount of free charge (q) present at the probe-solid interface

$$\frac{1}{q L} ( \frac{{d}^{2} {E}_{X *}}{dx} ) = \frac{dF}{dx} \frac{1}{q} \qquad ( 14 )$$

provides an expression of the same form as the Poisson equation

$$∇ \cdot \vec{E} = - \frac{ρ}{ɛ} \qquad ( 15 )$$

that relates the divergence of the electric field (\vec{E}) to the charge density (ρ) normalized by the permittivity of the medium, ε. As L represents a change in length (14), albeit a constant one, equating −∇·\vec{E} with the left-hand side of (14) and substituting (15) into the former after multiplying (14) by negative one yields

$$ρ = - \frac{dF}{dx} \frac{ɛ}{q} \qquad ( 16 )$$

and reveals that the interaction energy of the probe with the solid

$$( \frac{dF}{dx} )$$

is a direct measure of the charge density emerging from the solid in the near surface zone.

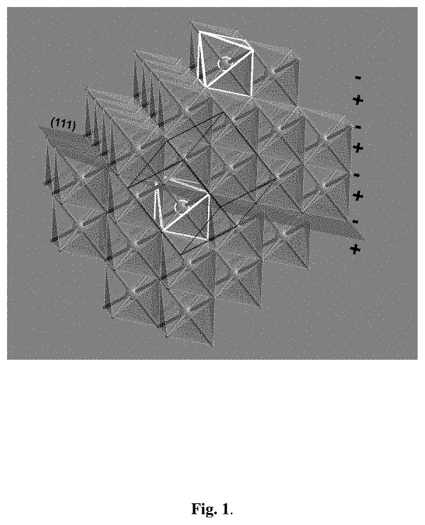

In FIG. 1, is a schematic rendering of the crystal structure of natural magnesium oxide (MgO). The magnesium octahedra in MgO form fixed layers of charge at (111) surfaces and exhibit a repeating symmetry (highlighted in white) that is characteristic of ionic oxides with rocksalt structure. Positively charge layers (+) and negatively charged layers (−) co-align with magnesium atoms (spheres at center of each octahedron) and oxygen atoms (at octahedral edges—not shown) respectively. In charge neutral lattices, a a divergence in polarization develops along the [111] crystal direction at surfaces as the bulk lattice cannot compensate the terminal layer.

In FIG. 2, the dependence of charge density (ρ) on the period (τ) of the modulation function depicted for natural MgO (MgO) and conductive monocrystalline magnesium oxide (MgO*). All materials exhibit persistent currents and measurable charge density; the current density and interaction energy of MgO* are anti-symmetric, which gives rise to a positive charge density in the inventive phase for all τ>0. The unit of measurement for τ is minutes.

In FIG. 3, the dependence of the imaginary contribution to the dielectric permittivity (ε″) and the electrical conductivity (σ) on frequency (inset) for natural magnesium oxide (MgO) and conductive monocrystalline magnesium oxide (MgO*). The ε″ of MgO* is upwards of an order of magnitude lower than that of natural MgO over the frequency range of 0.01 Hz to 0.1 Hz demonstrating the increased electrical stability of the inventive material. In this same frequency range, MgO* is upwards of twelve times more conductive than natural MgO.

In FIG. 4, the second order Raman spectrum of MgO* and MgO. Raman scattering intensity varies with Raman shift as measured in wavenumber (cm⁻¹) in both materials. The second order spectrum of MgO arises from points of high density of states (DOS) near the critical points in the Brillouin zone (Manson, et al, 1971). A significantly increased intensity in the 1019 cm⁻¹ Raman mode (grey area) demonstrates that MgO* has an increased vibrational DOS at this energy and as a result a larger number of accessible bonding states.

In FIG. 5, surface microtopographic maps acquired using atomic force microscopy (AFM). Mg(OH)₂ pillar structures grown from an undersaturated aqueous solution flowing at 5 mL/min over a natural MgO crystal (top) and a conductive monocrystalline MgO* (bottom) for 150 minutes illustrate the distinctive conductive properties of the inventive MgO* material. Seven fold higher growth rates and the continual assembly of pillars after the removal of tens of nanometers of the crystal demonstrate that the increased conductivity of the inventive material MgO* is resilient to large scale reconstruction of the crystal surface.

In FIG. 6, the evolution of force imposed on a uniaxial load cell platen by MgO and MgO* under conditions of zero axial stress and continuous exposure of the oxide single crystal surfaces to an undersaturated aqueous solution flowing at 5 ml/min. These results demonstrate a seven-fold increased rate of force development for the MgO* material relative to natural MgO and highlight that an enhanced flux of momentum is a property of the inventive material.

I claim:

1. An energy storage device, a wide band gap semiconductor, or a gate dielectric comprising a conductive monocrystalline magnesium oxide having a purity of at least 98% and an imaginary contribution to the dielectric permittivity (ε″) of at most 0.03 at a frequency of 0.031 Hz.

2. The energy storage device, a wide band gap semiconductor, or a gate dielectric of claim 1 wherein the conductive monocrystalline magnesium oxide has a positive charge density.

3. The energy storage device, a wide band gap semiconductor, or a gate dielectric of claim 2 wherein the conductive monocrystalline magnesium oxide has a purity of at least 99%.

4. The energy storage device, a wide band gap semiconductor, or a gate dielectric of claim 1 wherein the conductive monocrystalline magnesium oxide has a conductivity of at least 10^{-8.4} S*m⁻¹ at a frequency of 0.031 Hz.

5. The energy storage device, a wide band gap semiconductor, or a gate dielectric of claim 1 wherein the conductive monocrystalline magnesium oxide has an increased Raman scattering intensity in the 1019 cm⁻¹ range compared to natural monocrystalline magnesium oxide.

6. The energy storage device, a wide band gap semiconductor, or a gate dielectric of claim 1 wherein the conductive monocrystalline magnesium oxide has a charge density of at least 1000 C*m⁻³.

7. An energy storage device, a wide band gap semiconductor, or a gate dielectric comprising a conductive monocrystalline magnesium oxide having a purity of at least 98% and a conductivity of at least 10^{-8.4} S*m⁻¹ at a frequency of 0.031 Hz.

8. The energy storage device, a wide band gap semiconductor, or a gate dielectric of claim 7 wherein the conductive monocrystalline magnesium oxide has a positive charge density.

9. The energy storage device, a wide band gap semiconductor, or a gate dielectric of claim 8 wherein the conductive monocrystalline magnesium oxide has a purity of at least 99%.

10. The energy storage device, a wide band gap semiconductor, or a gate dielectric of claim 7 wherein the conductive monocrystalline magnesium oxide has an increased Raman scattering intensity in the 1019 cm⁻¹ range compared to natural monocrystalline magnesium oxide.

11. The energy storage device, a wide band gap semiconductor, or a gate dielectric of claim 7 wherein the conductive monocrystalline magnesium oxide has a charge density of at least 1000 C*m⁻³.

12. An energy storage device comprising at least one of electrodes, electrolytes, binders, or combinations thereof wherein said electrodes, electrolytes, binders, or combinations thereof comprises a conductive monocrystalline magnesium oxide having a purity of at least 98% and an imaginary contribution to the dielectric permittivity (ε″) of at most 0.03 at a frequency of 0.031 Hz.

13. An energy storage device comprising at least one of electrodes, electrolytes, binders, or combinations thereof wherein said electrodes, electrolytes, binders, or combinations thereof comprises a conductive monocrystalline magnesium oxide having a purity of at least 98% and having a conductivity of at least 10^{-8.4} S*m⁻¹ at a frequency of 0.031 Hz.

14. A wide band gap semiconductor comprising a conductive monocrystalline magnesium oxide having a purity of at least 98%, an imaginary contribution to the dielectric permittivity (ε″) of at most 0.03 at a frequency of 0.031 Hz, and having a conductivity of at least 10^{-8.4} S*m⁻¹ at a frequency of 0.031 Hz.

15. A gate dielectric comprising a conductive monocrystalline magnesium oxide having a purity of at least 98%, an imaginary contribution to the dielectric permittivity (ε″) of at most 0.03 at a frequency of 0.031 Hz, and having a conductivity of at least 10^{-8.4} S*m⁻¹ at a frequency of 0.031 Hz.
